(19) United States
(12) Patent Application Publication
(10) Pub. No.: US 2006/0137903 A1
(43) Pub. Date: Jun. 29, 2006

(54) Memory module circuit board layer routing

(76) Inventors: John T. Sprietsma, Portland, OR (US); Michael W. Leddige, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/021,706

(22) Filed: Dec. 23, 2004

(51) Int. Cl. H05K 7/06

(52) U.S. Cl. 174/255

(57) ABSTRACT

In some embodiments a memory module circuit board includes a first layer with a first surface adapted to couple a first plurality of memory devices to the circuit board, and a second layer with a first portion and a second portion, the first portion including a plurality of first signal paths coupled to the first plurality of memory devices and the second portion including a reference voltage plane. Other embodiments are described and claimed.

This application is related to an application entitled “Memory Module Routing” filed on even date herewith with the same inventors as this application, attorney docket number 042390.P20297.

### TECHNICAL FIELD

The inventions relate to memory module circuit board layer routing.

### BACKGROUND

Today's computer systems include memory, which is typically held on a memory module. A memory module typically includes a circuit board, such as a printed circuit board (PCB), with a number of integrated circuits (ICs), or chips, coupled to one or more surfaces of the circuit board. The chips may be memory devices to provide memory resources to a computing platform such as, for example, a personal computer (PC). One type of memory module uses dynamic random access memory (DRAM) chips in a dual data rate (DDR) manner. These modules may arrange the DRAM chips as a Single In-line Memory Module (SIMM) or as a Dual In-line Memory Module (DIMM), for example.

The circuit board (or PCB) may have a connector along one edge that is compatible with a socket connector on a motherboard for integration of the memory module into the computing platform. One type of technology known as a DDR2 DIMM, has an electrical connector with 240 pins.

Dual inline memory modules (DIMMS) include multiple DRAM chips coupled to the PCB. For example, some implementations typically include eight DRAM chips coupled to the circuit board. In order to provide error correction coding an extra chip (for example, a ninth DRAM chip) is added to implement parity bit checking. However, the addition of an additional chip can make it difficult for the signal lines to turn the corner to provide fly-by sequencing of the chips while still fitting the module in the dimensions of existing sockets.

Large capacity size DRAM chips, for example, for future Dual Data Rate 3 (DDR3) technology, are projected to reach a size where convention routing techniques will not allow nine DRAMs to be placed on a singe side of a 5.25 inch long DIMM module (18 DRAMs if double sided). The physical size of the DRAMs (typically greater than 12.5 mm), combined with decoupling capacitors and termination resistors, will not allow Error Correcting Code (ECC) modules to fit within the same form factor as non-ECC DIMMs. Error Correcting Code memory is a type of memory that includes special circuitry for testing the accuracy of data as it passes in and out of memory. Non-ECC modules can include eight DRAM chips and ECC modules can include nine DRAM chips, for example. When combined with fly-by topology used for the DDR3 Command and Address bus, for example, there is simply not enough room on the DIMM circuit board to route the bus.

The Fully Buffered DIMM (FBD) solution to this problem has previously been to increase the size of the DIMM. Increasing the form factor size of the DIMM goes against form factor trends and makes it difficult for a high end desktop or a low end server, for example, to support both non-ECC and ECC DIMMs with one motherboard design.

Another possible solution to this problem is to add four more layers to each side of the DIMM circuit board (for example, two for routing, one for power, and one for ground). This results in a DIMM circuit board with ten layers.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a non-ECC memory module according to some embodiments of the inventions.

FIG. 2 illustrates an ECC memory module according to some embodiments of the inventions.

FIG. 3 illustrates an ECC memory module that is compatible with non-ECC memory modules according to some embodiments of the inventions.

FIG. 4 illustrates a memory module according to some embodiments of the inventions.

FIG. 5 illustrates layers of a memory module according to some embodiments of the inventions.

FIG. 6 illustrates layers of a memory module according to some embodiments of the inventions.

### DETAILED DESCRIPTION

Some embodiments of the inventions relate to memory module routing to maintain Error Correcting Code (ECC) and non-ECC form factor compatibility.

In some embodiments a memory module circuit board includes a first surface adapted to couple a first plurality of memory devices, a plurality of signal lines, and a command and address bus coupled to the signal lines. The command and address bus is routed from the signal lines and adapted to couple to at least one of the first plurality of memory devices in a manner that does not require the command and address bus lines to turn more than approximately ninety degrees before coupling to the at least one of the first plurality of memory devices.

In some embodiments a memory module includes a circuit board having a first surface, a first plurality of memory devices coupled to the first surface, a plurality of signal lines, and a command and address bus coupled to the signal lines. The command and address bus is routed from the signal lines and adapted to couple to at least one of the first plurality of memory devices in a manner that does not require the command and address bus lines to turn more than approximately ninety degrees before coupling to the at least one of the first plurality of memory devices.

In some embodiments a system includes a motherboard and a memory module coupled to the motherboard. The memory module includes a circuit board having a first surface, a first plurality of memory devices coupled to the first surface, a plurality of signal lines, and a command and address bus coupled to the signal lines. The command and address bus is routed from the signal lines and adapted to couple to at least one of the first plurality of memory devices in a manner that does not require the command and address bus lines to turn more than approximately ninety degrees before coupling to the at least one of the first plurality of memory devices.

Some embodiments relate to a layered circuit board implementation to route ECC memory modules differently than non-ECC memory modules in order to maintain pin compatibility of the ECC memory modules and the non-ECC memory modules.

Some embodiments relate to a layered circuit board implementation to route memory modules.

In some embodiments a memory module circuit board includes a first layer with a first surface adapted to couple a first plurality of memory devices to the circuit board, and a second layer with a first portion and a second portion, the first portion including a plurality of first signal paths coupled to the first plurality of memory devices and the second portion including a reference voltage plane.

In some embodiments a memory module includes a first plurality of memory devices and a circuit board. The circuit board includes a first layer with a first surface, the first plurality of memory devices coupled to the first surface, and a second layer with a first portion and a second portion, the first portion including a plurality of first signal paths coupled to the first plurality of memory devices and the second portion including a reference voltage plane.

In some embodiments a system includes a motherboard and a memory module coupled to the motherboard. The memory module includes a first plurality of memory devices and a circuit board. The circuit board includes a first layer with a first surface, the first plurality of memory devices coupled to the first surface, and a second layer with a first portion and a second portion, the first portion including a plurality of first signal paths coupled to the first plurality of memory devices and the second portion including a reference voltage plane.

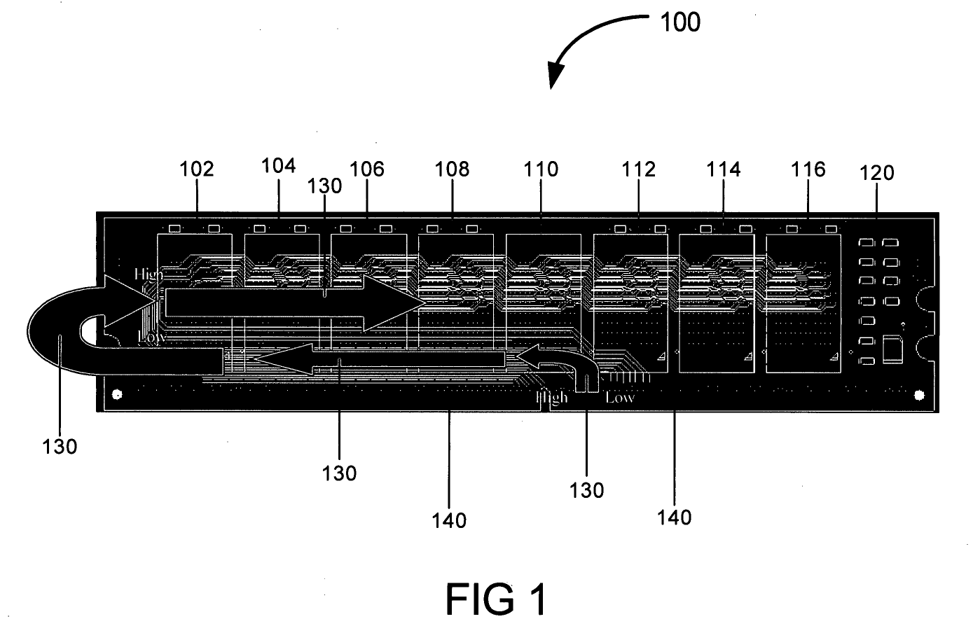

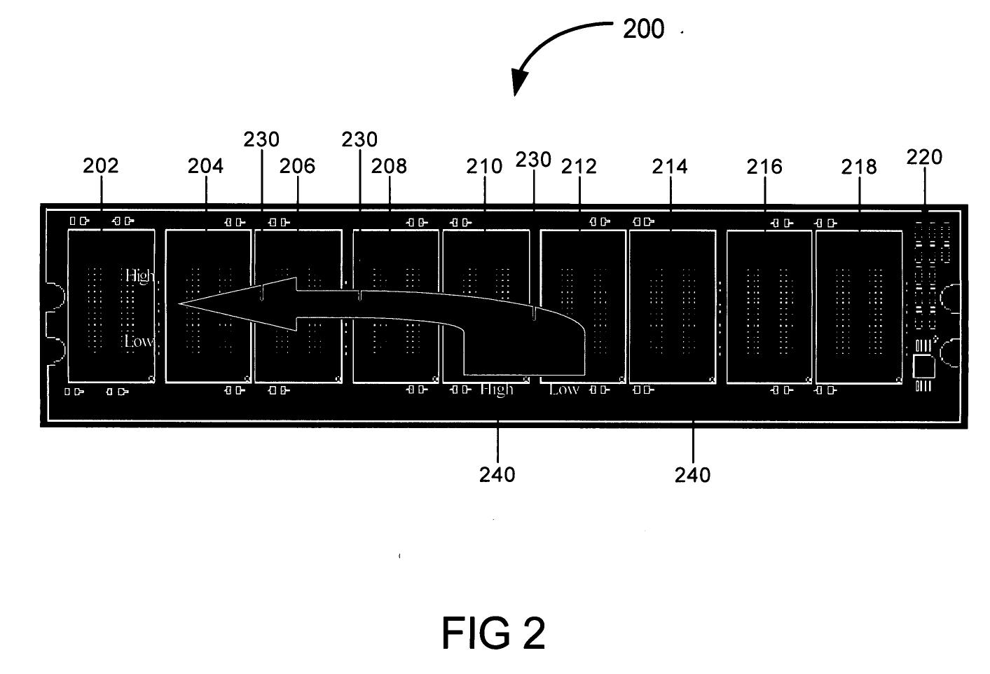

FIG. 1 illustrates a non-ECC memory module (for example DIMM) 100 according to some embodiments. Memory module 100 hold eight memory (for example, DRAM) Integrated Circuits (also referred to as ICs, chips, etc.) 102, 104, 106, 108, 110, 112, 114, and 116 and several termination resistors 120 on one side of the module (in FIG. 1, on the right side). The memory chips and/or termination resistors may be held by the memory module 100, may be soldered to the memory module 100, and/or may be coupled to the memory module 100. The arrows 130 illustrate how the fly-by topology for the command and address bus flows from the connector 140 at the bottom of the memory module 100 to the memory chips 102, 104, 106, 108, 110, 112, 114, and 116. In some embodiments, the pinout of the memory module 100 has been chosen to match the DDR2 (Double Data Rate 2) pinout in order to facilitate the migration from DDR2 to DDR3 (Double Data Rate 3) technology. Connector 140 is not shown in complete detail in FIG. 1 but is at the bottom of memory module 100. Connector 140 may be similar and/or the same to connector 240 illustrated in FIG. 2, for example. As illustrated in FIG. 1, the high and low order address pins naturally connect with and then turn in a manner necessary to enter the memory chips on the left side of the module 100, and length matching is easier since the low and high order pins each get an “inside” turn and an “outside” turn radius. The first branch arrow 130 routes to the left and keeps the bits in order by turning the corner. In this manner, the non-ECC DIMM 100 is routable with a minimum number of Printed Circuit Board (PCB) layers (for example, in six PCB layers).

FIG. 2 illustrates an ECC memory module (for example, ECC DIMM) 200 according to some embodiments. ECC memory module 200 holds nine memory chips 202, 204, 206, 208, 210, 212, 214, 216, and 218, several terminal resistors 220 on one side of the memory module 200 (in FIG. 2, on the right side), and includes a connector 240 (at the bottom of memory module 200 in FIG. 2). It is noted that in some embodiments ECC memory module 200 holds eighteen memory chips including the nine memory chips illustrated in FIG. 2 and nine additional memory chips on the bottom side of the memory module. The memory chips and/or termination resistors may be held by the memory module 200, may be soldered to the module 200, and/or may be coupled to the module 200. A problem occurs when adding the ninth memory chip (or ECC memory chip, or ECC DRAM, for example) to the memory module. As illustrated in FIG. 2, there is no room on the left side of module 200 of FIG. 2 to allow the routing (arrows 230) to make the turn in a manner similar to that illustrated in FIG. 1. This problem can be compensated for by adding an internal wiring layer, routing to the left side of the left most memory chip 202, and then continuing through the memory chip array area through memory chips 202, 204, 206, 208, 210, 212, 214, 216, and 218 to reach the termination resistors 220 on the right side of the memory module 200.

A problem with the type of compensation described above in reference to FIG. 2 is that the locations of the address bus needs to “un-twist” to be able to make the memory module (for example, DIMM) connectivity work correctly. The arrow 230 showing the relative width of the command and access bus would have the high bits on the connector connected to the low bits of the memory chip, which cannot work. In order to “flip” or “un-twist” the bus, a minimum of one additional via per signal (or approximately 30 total minimum vias) would be needed to change the ordering of the bits. However, the pads of the memory chips take up a large enough space that makes this a difficult or impractical solution, particularly since the vias need to be in a very small area in order to flip the bus.

Alternatively, changing the pinout at the connector 240 could also solve the problem. However, this completely eliminates the possibility of supporting ECC and non-ECC memory modules using the same motherboard. Rotating the memory chips 202, 204, 206, 208, 210, 212, 214, 216, and 218 would help to fix the command and address bus (C/A bus) problem, but would break the data bus routing from the connector pins straight up to the memory chips.

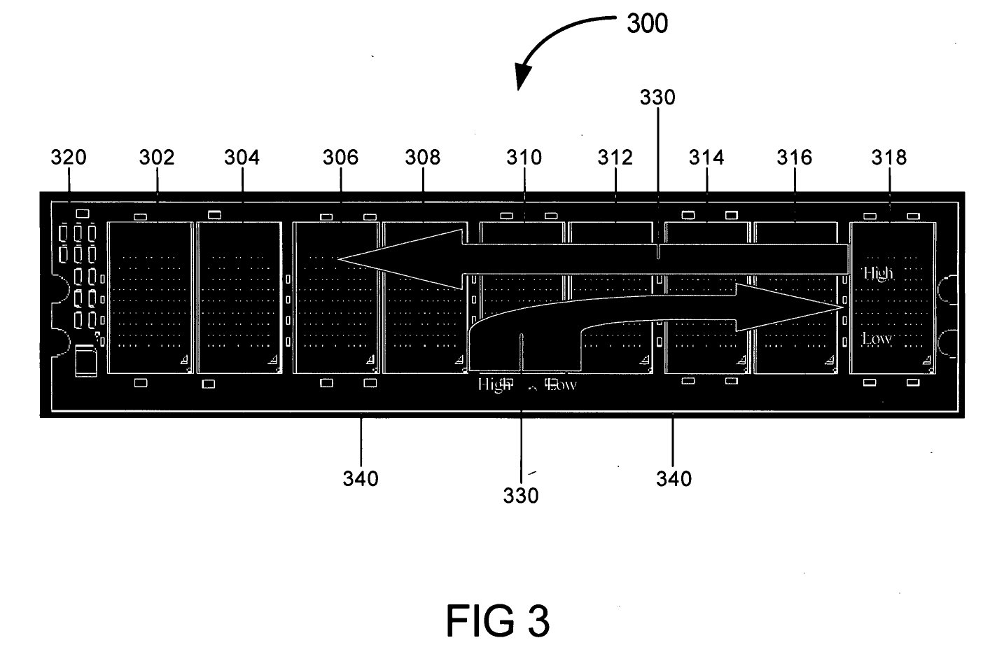

FIG. 3 illustrates an ECC memory module (for example, ECC DIMM) 300 according to some embodiments. Memory module 300 holds nine memory (for example, DRAM) Integrated Circuits (also referred to as ICs, chips, etc.) 302, 304, 306, 308, 310, 312, 314, 316, and 318, and several termination resistors 320 on one side of the memory module (in FIG. 3, on the left side). The memory chips and/or termination resistors may be held by the memory module 300, may be soldered to the memory module 300, and/or may be coupled to the memory module 300. The arrows 330 illustrate how the fly-by topology for the command and address bus flows from the connector 340 at the bottom of the memory module 300 to the memory chips 318, 316, 314, 312, 310, 308, 306, 304, and 302. In some embodiments, the pinout of the memory module 300 has been chosen to match the DDR2 (Double Data Rate 2) pinout to facilitate the migration from DDR2 to DDR3 (Double Data Rate 3) technology. Connector 340 is not shown in complete detail in FIG. 3 but is at the bottom of module 300. Connector 340 may be similar to and/or the same as connector 240 illustrated in FIG. 2, for example.

As illustrated in FIG. 3, the high and low order address pins naturally connect with the memory chips in a manner necessary to enter the memory chips on the left side of the memory chip 318 located on the right side of module 300. The high and low bits are kept in order by routing to the right without turning the corner. The flow 330 of the command and address bus is changed in some embodiments by having it go first to the right-most memory chip 318 and then going through memory chips 316, 314, 312, 310, 308, 306, 304 and 302 toward termination on the left side of memory module 300. In the lower arrow 330 of FIG. 3, the high bits of the command and address bus start at the left and move to the top of the arrow and connect naturally with the upper arrow 330, without requiring any additional turn at the right side of memory module 300. The command and address bus is automatically flipped, no additional vias are required, and the memory module 300 is routable.

The automatic flipping of the command and address bus without requiring additional vias can be implemented in some embodiments by having the command and address bus couple to the connector 340 in a separate layer from the layer to which the memory chips are coupled so that the bus runs from below the central portion of connector 340 to a portion of the separate layer that is generally under memory chip 318 so that it runs in that separate layer generally under the bottom arrow 330. In such embodiments that portion of the command and address bus is then coupled to another portion of the command and address bus that extends in yet another layer from below the memory chip 318 across to the other memory chips so that it runs in that yet another layer generally under the top arrow 330 in FIG. 3.

Automatic flipping of the command and address bus allows an ECC memory module such as an ECC DIMM to be laid out with a different wiring style than an ECC memory module. In this manner ECC memory modules and non-ECC memory modules may be laid out with a different wiring style while maintaining a compatible edge finger pinout. This is particularly advantageous, for example, for an ECC DDR3 memory module.

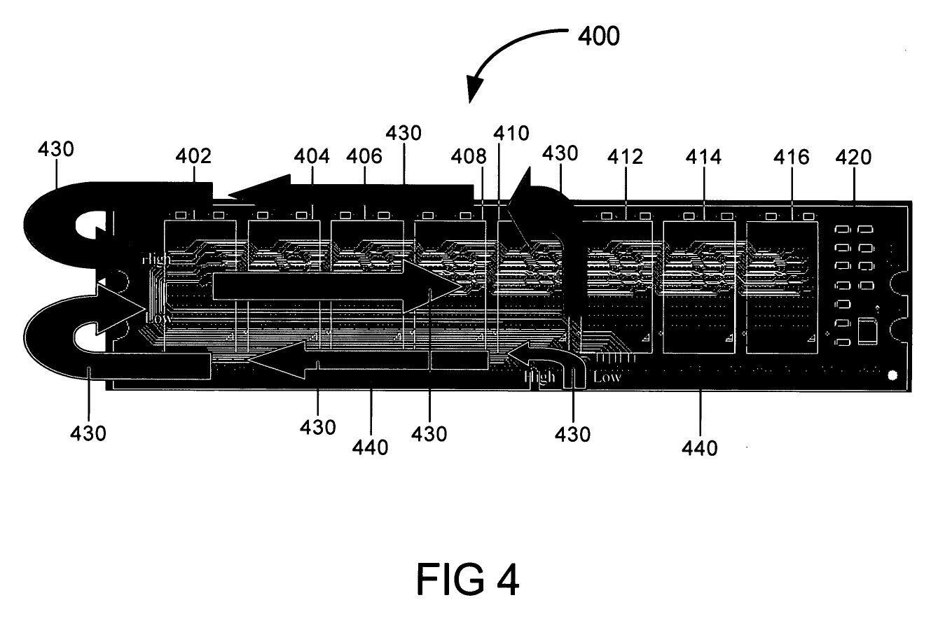

FIG. 4 illustrates a non-ECC memory module (for example, non-ECC DIMM) 400 according to some embodiments. Memory module 400 holds eight memory chips (for example, DRAM chips) 402, 404, 406, 408, 410, 412, 414, and 416 and several termination resistors 420 on one side of the module (in FIG. 4, on the right side). The memory chips and/or termination resistors may be held by the memory module 400, may be soldered to the memory module 400, and/or may be coupled to the memory module 400. The arrows 430 illustrate how the fly-by topology for the command and address bus flows from the connector 440 at the bottom of the memory module 400 to the memory chips 402, 404, 406, 408, 410, 412, 414, and 416. The arrows 430 of FIG. 4 are arranged in two sub-flows, one illustrated at the top of the memory module 400 and one illustrated at the bottom of memory module 400. The first branch of the address and command bus (either of the arrows 430 shown in the middle of module 400 going up and to the left) is a connection on the PCB from the connector 440 to the first memory chip 402. The branch can be routed under the memory chip (or DRAM) 402, or over the top of the memory chip (or DRAM) 402. A second branch of the address and command bus (arrow 430 shown from left to right in FIG. 4) provides connections from the first memory chip 402 to the other memory chips 404, 406, 408, 410, 412, 414, 416. Turning the corner in either of these manners keeps the bits in the command and address bus in order from high to low. In some embodiments, the pinout of the memory module 400 has been chosen to match the DDR2 (Double Data Rate 2) pinout to facilitate the migration from DDR2 to DDR3 (Double Data Rate 3) technology. Connector 440 is not shown in complete detail in FIG. 1 but is at the bottom of memory module 400. Connector 440 may be similar to connector 240 illustrated in FIG. 2, for example. As illustrated in FIG. 4, the high and low order address pins naturally connect with and then turn in a manner necessary to enter the memory chip 402 on the left side of the memory module 400, and length matching is easier since the low and high order pins each get an “inside” turn and an “outside” turn radius. In this manner, the non-ECC memory module 400 is routable with a minimum number of Printed Circuit Board (PCB) layers (for example, in six PCB layers).

In order to allow memory modules such as DDR3 memory modules to be supported in a four layer motherboard, it is necessary to have the data signals reference the ground planes and the command and address (C/A) signals reference the power planes for their return currents in a manner similar to that in DDR2. In order to double the maximum data rate beyond that of DDR2, however, DDR3 has adopted a fly-by topology for the command and address bus. Attempts at routing this topology have required additional layers to be added to the memory module (DIMM) to maintain four layer motherboard compatibility. Adding an ECC device to the memory module (DIMM) further complicates the routing design by eliminating any extra board area to let the command and access bus turn around at the end of the memory module. This problem may be overcome by using a symmetrical PCB stackup layering technique by splitting power layers and/or ground layers with signals to minimize the number of layers necessary to route large memory modules such as DDR3 memory modules.

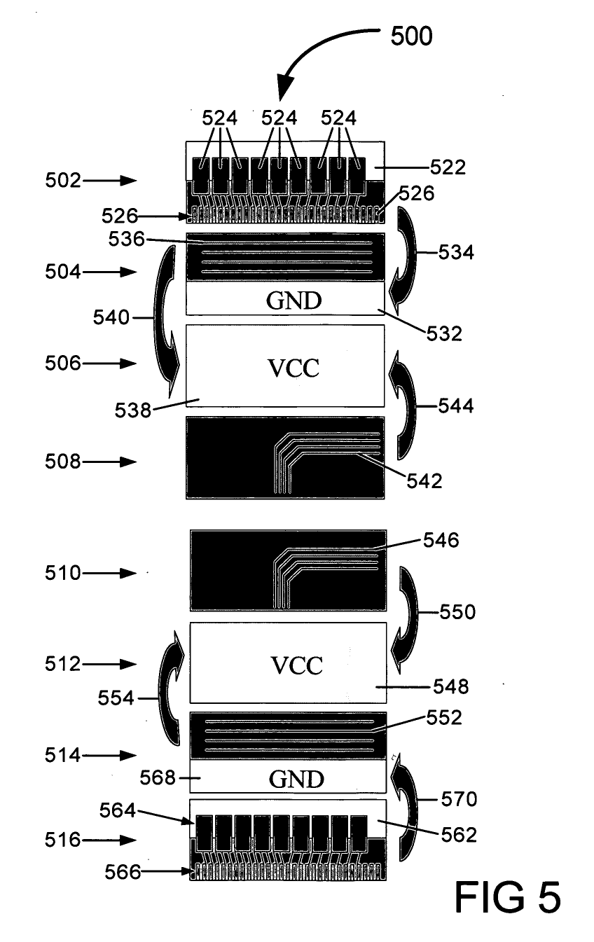

FIG. 5 illustrates a memory module 500 including a layered circuit board according to some embodiments. Memory module 500 includes a circuit board (for example, a PCB) having a first layer 502, a second layer 504, a third layer 506, a fourth layer 508, a fifth layer 510, a sixth layer 512, a seventh layer 514, and an eighth layer 516. In some embodiments memory module 500 is a DIMM. In some embodiments memory module 500 includes nine memory chips 524 (for example, DRAM memory chips).

The first layer 502 includes a surface 522 with a plurality of memory chips 524 (for example, DRAM memory chips) coupled thereto, for example by solder. Memory chips 524 are coupled (for example, by lines on the surface 522) to a plurality of data lines 526 included within a connector on the first layer 502. The data lines 526 of the first layer 502 are referenced to a ground portion (ground voltage reference plane) 532 of the second layer 504 as illustrated by arrow 534. Command and/or address bus lines 536 of the second layer 504 are referenced to a Vcc portion (Vcc voltage reference plane) 538 of third layer 506 as illustrated by arrow 540. Command and/or address bus lines 536 are also referred to as a second branch, for example corresponding to the top arrow 330 of FIG. 3. The second branch (also referred to as a “flyby”) connects the first memory chip (for example, DRAM) to the rest of the memory chips (for example, DRAMs). Command and/or address bus lines 542 of the fourth layer 508 are also referenced to the Vcc portion 538 of third layer 506 as illustrated by arrow 544. Command and/or address bus lines 542 are also referred to as a first branch, for example corresponding to the bottom arrow 330 of FIG. 3. The first branch is a connection on the circuit board (PCB) from the connector to the first memory chip (for example, DRAM).

In some embodiments it is noted that first branch routings enter the memory chips on a right side in an ECC memory module with eight layers such as the memory module 500 illustrated in FIG. 5. In some embodiments in which a six layer solution is used (for example, in a non-ECC memory module) branch routing needs to enter the left side of the memory chips.

Command and/or address bus lines 546 of the fifth layer 510 are referenced to a Vcc portion (Vcc voltage reference plane) 548 of sixth layer 512 as illustrated by arrow 550. Command and/or address bus lines 544 are also referred to as a first branch, for example corresponding to the bottom arrow 330 of FIG. 3. Command and/or address bus lines 552 of the seventh layer 514 are also referenced to the Vcc portion 548 of sixth layer 512 as illustrated by arrow 554. Command and/or address bus lines 552 are also referred to as a second branch, for example corresponding to the top arrow 330 of FIG. 3.

The eighth layer 516 includes a surface 562 with a plurality of memory chips 564 coupled thereto, for example by lines on the surface 562. Memory chips 564 are coupled to a plurality of data lines 566 included within a connector on the eighth layer 516. The data lines 566 of the eighth layer 516 are referenced to a ground portion (ground voltage reference plane) 568 of the seventh layer 514 as illustrated by arrow 570.

The routing per each layer illustrated in FIG. 5 maintains the signal referencing that is required for the return currents of the signal lines. Data lines are always referenced to ground, and the command and address bus lines are always referenced to Vcc. DDR3 DRAM contact ball assignments have been laid out such that there are four signals in every row of contact balls on the DRAM chip. In order to achieve spacing rules of 10 mils or more (for crosstalk control) it becomes important to use two routing layers for signals going in each direction. A configuration according to some embodiments that uses split power/routing planes (or layers) provides a solution for routing a DDR3 ECC DIMM that is less than ten layers. According to some embodiments a board with eight layers may be used in order to provide a cost savings of almost 25% for the bare board as compared to other implementations.

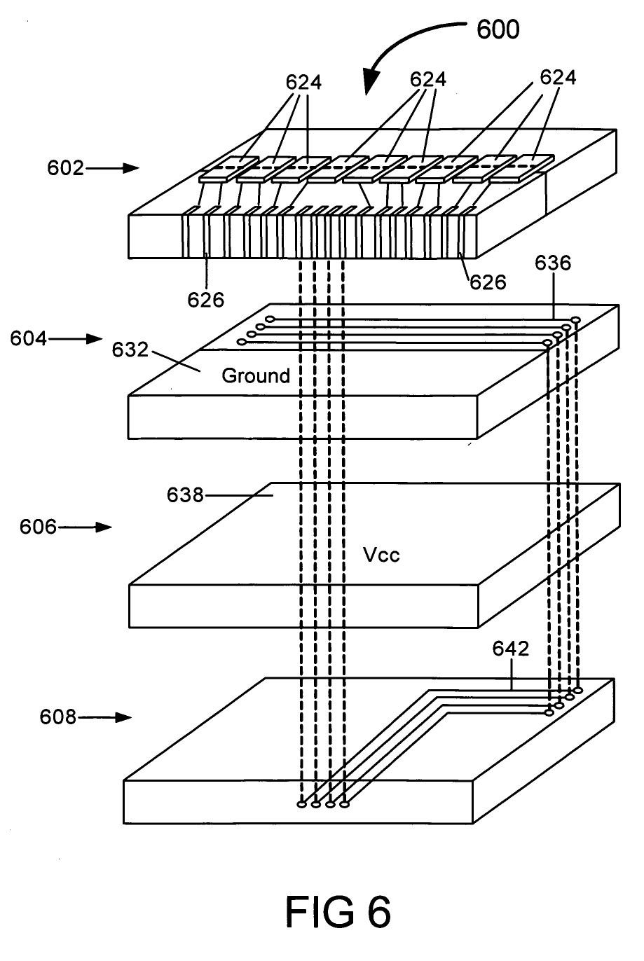

FIG. 6 illustrates a portion of a memory module 600 according to some embodiments. Memory module 600 includes a circuit board (for example, a PCB) having a first layer 602, a second layer 604, a third layer 606, and a fourth layer 608. In some embodiments memory module 600 also includes fifth, sixth, seventh, and eighth layers which mirror the fourth layer 608, the third layer 606, the second layer 604, and the first layer 602, respectively. In some embodiments memory module 600 is a DIMM. In some embodiments memory module 600 includes nine memory chips 624 (for example, DRAM memory chips).

The first layer 602 includes a surface 622 with a plurality of memory chips 624 (for example, DRAM memory chips) coupled thereto, for example by solder. Memory chips 624 are coupled (for example, by lines on the surface 622) to a plurality of data lines 626 included within a connector on the first layer 602. The data lines 626 of the first layer 602 are referenced to ground (for example, to ground portion 632 of the second layer 604). Command and/or address bus lines 636 of the second layer 604 are referenced to Vcc (for example, to a Vcc voltage reference plane portion 638 of third layer 606). Command and/or address bus lines 636 are also referred to as a second branch, for example corresponding to the top arrow 330 of FIG. 3. Command and/or address bus lines 642 of the fourth layer 608 (a signal layer) are also referenced to Vcc (for example, to the Vcc portion 638 of third layer 606). Command and/or address bus lines 642 are also referred to as a first branch, for example corresponding to the bottom arrow 330 of FIG. 3.

Command and/or address bus lines 642 have been illustrated in FIG. 6 as turning at a right angle. However, they may curve and/or they may turn in segments such as command and/or address bus lines 542 illustrated in FIG. 5, or may be directed in any sort of manner to connect the ends of the command and/or address bus lines 642 together. Similarly, command and/or bus lines 542 illustrated in FIG. 5 may move in any manner. A first end of command and/or bus lines 642 are coupled to some of the data lines 626 of the first layer, as illustrated by dotted lines in FIG. 6. A second end of command and/or bus lines 642 are coupled to command and/or bus lines 636, as illustrated by additional dotted lines in FIG. 6. In this manner high bits of the command and address bus can start at the left end of the first end of the command and/or address bus lines 642, and move to the second end of the command and/or address bus lines 642 to connect naturally with the command and/or address bus lines 636 without requiring any additional turn at the right side of memory module 600.

The layer arrangement of memory module 600 as illustrated in FIG. 6 allows the data lines 626 to reference ground and the command and access bus lines 636 and 642 to reference Vcc in a manner similar to that of the motherboard to which the memory module 600 can be coupled. This provides the same socket footprint in order to provide legacy compatibility and for sockets designed for non-ECC memory modules, and can also provide the same form factor as for non-ECC memory modules. In some embodiments the arrangement can also allow a non-ECC DIMM to be implemented in eight layers (rather than ten or more layers).

Although some embodiments have been described as relating to DIMMs and/or to DDR3, for example, other implementations are possible according to some embodiments, and the embodiments of the inventions are not necessarily limited to DIMMs or to DDR3, for example. Specifically, some embodiments may be implemented on any type of memory module and is not limited to a DIMM implementation and/or to a DDR3 implementation, for example.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state, or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A memory module circuit board comprising:
a first layer with a first surface adapted to couple a first plurality of memory devices to the circuit board;
a second layer with a first portion and a second portion, the first portion including a plurality of first signal paths coupled to the first plurality of memory devices and the second portion including a reference voltage plane.

2. The memory module circuit board of claim 1, wherein the plurality of first signal paths comprise a command and address bus.

3. The memory module circuit board of claim 1, wherein the reference voltage plane is at least a selected one of a ground voltage reference plane and a Vcc voltage reference plane.

4. The memory module circuit board of claim 1, wherein the reference voltage plane is a ground voltage plane.

5. The memory module circuit board of claim 4, further comprising data lines on the first surface that are referenced to the ground voltage plane.

6. The memory module circuit board of claim 1, further comprising a third layer that includes a second reference voltage plane.

7. The memory module circuit board of claim 6, wherein the second reference voltage plane is a Vcc power voltage plane.

8. The memory module circuit board of claim 6, further comprising a fourth layer that includes a second plurality of signal paths.

9. The memory module circuit board of claim 8, wherein the second plurality of signal paths is referenced to the second reference voltage plane.

10. The memory module circuit board of claim 8, wherein the second reference voltage plane is a Vcc power voltage plane, and wherein the plurality of first signal paths and the plurality of second signal paths are referenced to the Vcc power voltage plane.

11. The memory module circuit board of claim 8, wherein the second reference voltage plane is a Vcc power voltage plane, and wherein the plurality of first signal paths and the plurality of second signal paths are referenced to the Vcc power voltage plane.

12. The memory module circuit board of claim 7, wherein the plurality of first signal paths are referenced to the Vcc power voltage plane.

13. The memory module circuit board of claim 1, wherein the reference voltage plane is a ground voltage plane, the memory module circuit board further comprising:
a plurality of data lines on the first surface that are referenced to the ground voltage plane;
a third layer that includes a Vcc power reference voltage plane, wherein the plurality of first signal lines are referenced to the Vcc power reference voltage plane;
a fourth layer that includes a plurality of second signal paths, wherein the plurality of second signal paths are coupled to the plurality of data lines and to the plurality of first signal paths, and are referenced to the Vcc power reference voltage plane.

14. The memory module circuit board of claim 1, wherein the reference voltage plane is a first ground voltage plane, the memory module circuit board further comprising:
a plurality of first data lines on the first surface that are referenced to the first ground voltage plane;
a third layer that includes a first Vcc power reference voltage plane, wherein the plurality of first signal lines are referenced to the first Vcc power reference voltage plane;
a fourth layer that includes a plurality of second signal paths, wherein the plurality of second signal paths are coupled to the plurality of first data lines and to the plurality of first signal paths, and are referenced to the first Vcc power reference voltage plane;
an eighth layer with a second surface adapted to couple a second plurality of memory devices to the circuit board, and including a second plurality of data lines;
a seventh layer with a first portion and a second portion, the first portion of the seventh layer including a plurality of third signal paths coupled to the second plurality of memory devices and the second portion of the seventh layer including a second ground voltage plane, wherein the second plurality of data lines is referenced to the second ground voltage;
a sixth layer that includes a second Vcc power reference voltage plane, wherein the plurality of third signal lines are referenced to the second Vcc power reference voltage plane; and
a fifth layer that includes a plurality of fourth signal paths, wherein the plurality of fourth signal paths are coupled to the plurality of second data lines and to the plurality of third signal paths, and are referenced to the second Vcc power reference voltage plane.

15. A memory module comprising:
a first plurality of memory devices; and
a circuit board including:
a first layer with a first surface, the first plurality of memory devices coupled to the first surface;
a second layer with a first portion and a second portion, the first portion including a plurality of first signal paths coupled to the first plurality of memory devices and the second portion including a reference voltage plane.

16. The memory module of claim 15, wherein the plurality of first signal paths comprise a command and address bus.

17. The memory module of claim 15, wherein the reference voltage plane is at least a selected one of a ground voltage reference plane and a Vcc voltage reference plane.

18. The memory module of claim 15, wherein the reference voltage plane is a ground voltage plane.

19. The memory module of claim 18, further comprising data lines on the first surface that are referenced to the ground voltage plane.

20. The memory module of claim 15, further comprising a third layer that includes a second reference voltage plane.

21. The memory module of claim 20, wherein the second reference voltage plane is a Vcc power voltage plane.

22. The memory module of claim 20, further comprising a fourth layer that includes a second plurality of signal paths.

23. The memory module of claim 22, wherein the second plurality of signal paths is referenced to the second reference voltage plane.

24. The memory module of claim 22, wherein the second reference voltage plane is a Vcc power voltage plane, and wherein the plurality of first signal paths and the plurality of second signal paths are referenced to the Vcc power voltage plane.

25. The memory module of claim 22, wherein the second reference voltage plane is a Vcc power voltage plane, and wherein the plurality of first signal paths and the plurality of second signal paths are referenced to the Vcc power voltage plane.

26. The memory module of claim 21, wherein the plurality of first signal paths are referenced to the Vcc power voltage plane.

27. The memory module of claim 15, wherein the reference voltage plane is a ground voltage plane, the memory module circuit board further comprising:
a plurality of data lines on the first surface that are referenced to the ground voltage plane;
a third layer that includes a Vcc power reference voltage plane, wherein the plurality of first signal lines are referenced to the Vcc power reference voltage plane;
a fourth layer that includes a plurality of second signal paths, wherein the plurality of second signal paths are coupled to the plurality of data lines and to the plurality of first signal paths, and are referenced to the Vcc power reference voltage plane.

28. The memory module of claim 15, wherein the reference voltage plane is a first ground voltage plane, the memory module circuit board further comprising:
a plurality of first data lines on the first surface that are referenced to the first ground voltage plane;
a third layer that includes a first Vcc power reference voltage plane, wherein the plurality of first signal lines are referenced to the first Vcc power reference voltage plane;
a fourth layer that includes a plurality of second signal paths, wherein the plurality of second signal paths are coupled to the plurality of first data lines and to the plurality of first signal paths, and are referenced to the first Vcc power reference voltage plane;
an eighth layer with a second surface adapted to couple a second plurality of memory devices to the circuit board, and including a second plurality of data lines;
a seventh layer with a first portion and a second portion, the first portion of the seventh layer including a plurality of third signal paths coupled to the second plurality of memory devices and the second portion of the seventh layer including a second ground voltage plane, wherein the second plurality of data lines is referenced to the second ground voltage;
a sixth layer that includes a second Vcc power reference voltage plane, wherein the plurality of third signal lines are referenced to the second Vcc power reference voltage plane; and
a fifth layer that includes a plurality of fourth signal paths, wherein the plurality of fourth signal paths are coupled to the plurality of second data lines and to the plurality of third signal paths, and are referenced to the second Vcc power reference voltage plane.

29. A system comprising:
a motherboard; and
a memory module coupled to the motherboard, the memory module comprising:
a first plurality of memory devices; and
a circuit board including:
a first layer with a first surface, the first plurality of memory devices coupled to the first surface;
a second layer with a first portion and a second portion, the first portion including a plurality of first signal paths coupled to the first plurality of memory devices and the second portion including a reference voltage plane.

30. The system of claim 29, wherein the plurality of first signal paths comprise a command and address bus.

31. The system of claim 29, wherein the reference voltage plane is at least a selected one of a ground voltage reference plane and a Vcc voltage reference plane.

32. The system of claim 29, wherein the reference voltage plane is a ground voltage plane.

33. The system of claim 32, further comprising data lines on the first surface that are referenced to the ground voltage plane.

34. The system of claim 29, further comprising a third layer that includes a second reference voltage plane.

35. The system of claim 34, wherein the second reference voltage plane is a Vcc power voltage plane.

36. The system of claim 34, further comprising a fourth layer that includes a second plurality of signal paths.

37. The system of claim 36, wherein the second plurality of signal paths is referenced to the second reference voltage plane.

38. The system of claim 36, wherein the second reference voltage plane is a Vcc power voltage plane, and wherein the plurality of first signal paths and the plurality of second signal paths are referenced to the Vcc power voltage plane.

39. The system of claim 36, wherein the second reference voltage plane is a Vcc power voltage plane, and wherein the plurality of first signal paths and the plurality of second signal paths are referenced to the Vcc power voltage plane.

40. The system of claim 35, wherein the plurality of first signal paths are referenced to the Vcc power voltage plane.

41. The system of claim 29, wherein the reference voltage plane is a ground voltage plane, the memory module further comprising:
a plurality of data lines on the first surface that are referenced to the ground voltage plane;
a third layer that includes a Vcc power reference voltage plane, wherein the plurality of first signal lines are referenced to the Vcc power reference voltage plane;
a fourth layer that includes a plurality of second signal paths, wherein the plurality of second signal paths are coupled to the plurality of data lines and to the plurality of first signal paths, and are referenced to the Vcc power reference voltage plane.

42. The system of claim 29, wherein the reference voltage plane is a first ground voltage plane, the memory module further comprising:
a plurality of first data lines on the first surface that are referenced to the first ground voltage plane;
a third layer that includes a first Vcc power reference voltage plane, wherein the plurality of first signal lines are referenced to the first Vcc power reference voltage plane;
a fourth layer that includes a plurality of second signal paths, wherein the plurality of second signal paths are coupled to the plurality of first data lines and to the plurality of first signal paths, and are referenced to the first Vcc power reference voltage plane;
an eighth layer with a second surface adapted to couple a second plurality of memory devices to the circuit board, and including a second plurality of data lines;
a seventh layer with a first portion and a second portion, the first portion of the seventh layer including a plurality of third signal paths coupled to the second plurality of memory devices and the second portion of the seventh layer including a second ground voltage plane, wherein the second plurality of data lines is referenced to the second ground voltage;
a sixth layer that includes a second Vcc power reference voltage plane, wherein the plurality of third signal lines are referenced to the second Vcc power reference voltage plane; and
a fifth layer that includes a plurality of fourth signal paths, wherein the plurality of fourth signal paths are coupled to the plurality of second data lines and to the plurality of third signal paths, and are referenced to the second Vcc power reference voltage plane.
